(19) United States
(12) Patent Application Publication
(10) Pub. No.: US 2003/0180659 A1
(43) Pub. Date: Sep. 25, 2003

(54) Resist composition

(76) Inventors: Yoshiyuki Takata, Osaka (JP); Hiroshi Moriuma, Osaka (JP); Koji Kuwana, Osaka (JP)

Correspondence Address: BIRCH STEWART KOLASCH & BIRCH, PO BOX 747, FALLS CHURCH, VA, 22040-0747, US

(21) Appl. No.: 10/350,005

(22) Filed: Jan. 24, 2003

(30) Foreign Application Priority Data
Jan. 25, 2002 (JP) 2002-016611

(51) Int. Cl. G03F 7/038

(52) U.S. Cl. 430/270.1; 430/905

(57) ABSTRACT

The present invention provides a resist composition comprising: a resin which has a structural unit represented by the following formula (I)

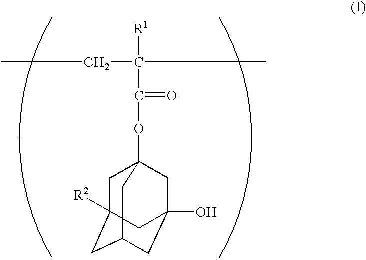

wherein R¹ represents hydrogen or methyl and R² represents hydrogen or hydroxyl, and which itself is insoluble or slightly soluble in an aqueous alkali solution but becomes soluble in an aqueous alkali solution by the action of an acid; a solvent containing at least one selected from the group consisting of propylene glycol monomethyl ether, methyl 2-hydroxyisobtyrate and 3-methoxy-1-butanol; and an acid generating agent.

### BACKGROUND OF THE INVENTION

1. Field of the Invention

The present invention relates to resist compositions used in the fine processing of a semiconductor.

2. Prior Art

In the fine processing of a semiconductor, a lithography process using a resist composition is usually adopted. In lithography, it is theoretically possible to increase resolution higher as exposure wavelength is shorter, as represented by the Rayleigh diffraction limit formula. The lithography exposure light source used in production of semiconductors include g ray having a wavelength of 436 nm, i ray having a wavelength of 365 nm and KrF excimer laser having a wavelength of 248 nm, the wavelength becoming shorter year by year. ArF excimer laser having a wavelength of 193 nm is promising as the exposure light source of the next generation.

Since a lens used in an ArF excimer laser exposure machine has a shorter life compared with the life of those used in conventional exposure light sources, it is desirable that the time period of exposure to ArF excimer laser light is as short as possible. As the sensitivity of a resist is required to be enhanced for the purpose above, so-called chemical amplifying type resist utilizing a catalytic action of an acid generated by exposure, and containing a resin having a group that is cleaved by the action of the acid is used.

It is known that, as a resin used in a resist for ArF excimer laser exposure, those having no aromatic ring for securing the transmittance of a resist, and having an alicyclic ring instead of an aromatic ring for obtaining dry etching resistance are advantageous. Various kinds of resins such as those described in Journal of Photopolymer Science and Technology, Vol. 9, No. 3, pages 387-398 (1996) by D. C. Hofer, are heretofore known as such resins. Also, use of an alternating copolymer composed of a structural unit derived from an alicyclic olefin and a structural unit derived from an unsaturated dicarboxylic acid anhydride (Proc. SPIE, Vol. 2724, pages 355-364 (1996) by T. I. Wallow et al.), a polymer having a structural unit derived from an alicyclic lactone (JP-A-2000-26446), or the like has been know as a resin in a resist for ArF excimer laser exposure.

Conventionally, as a solvent for a resist, glycol ether esters, esters, ketones, cyclic esters and the like have been used. However, conventional solvents had problems with solubility of a resin in which a polymer having a structural unit derived from 3-hydroxy-1-adamantyl (meth)acrylate or a structural unit derived from 3,5-dihydroxy-1-adamantyl (meth)acrylate is used (“(meth)acrylate” referred to herein means acrylate or methacrylate).

An object of the present invention is to provide a chemical amplifying type positive resist composition which is suitable for use in excimer laser lithography utilizing ArF, KrF or the like, and has satisfactory solubility even though a resin is used having a structural unit derived from 3-hydroxy-1-adamantyl (meth)acrylate or a structural unit derived from 3,5-dihydroxy-1-adamantyl (meth)acrylate.

### SUMMARY OF THE INVENTION

The present invention concerns a resist composition comprising: a resin which has a structural unit represented by the following formula (I)

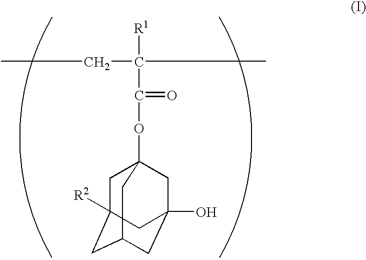

wherein R¹ represents hydrogen or methyl and R² represents hydrogen or hydroxyl, and which itself is insoluble or slightly soluble in an aqueous alkali solution but becomes soluble in an aqueous alkali solution by the action of an acid; a solvent containing at least one selected from the group consisting of propylene glycol monomethyl ether, methyl 2-hydroxyisobtyrate and 3-methoxy-1-butanol; and an acid generating agent.

### DETAILED DESCRIPTION OF PREFERRED EMBODIMENTS

In general, a resist composition in the liquid state in which components are dissolved in a solvent, are applied onto a substrate such as a silicone wafer according to a conventional method such as a spin coating method. The solvent used for the resist composition requires capability of dissolving each of the components, exhibiting a suitable drying rate and giving a uniform and smooth coating film after evaporation of the solvent.

The resist composition of the present invention comprises at least one selected from the group consisting of propylene glycol monomethyl ether, methyl 2-hydroxyisobutyrate and 3-methoxy-1-butanol as a solvent component.

In view of the solubility, the solvent used for the present invention is preferably a solvent containing at least 10% by weight of propylene glycol monomethyl ether, a solvent containing at least 40% by weight of methyl 2-hydroxyisobutyrate or a solvent containing at least 10% by weight of 3-methoxy-1-butanol.

Moreover, in view of balance of the solubility and coating characteristics, the solvent used for the present invention is preferably a solvent containing 10-80% by weight of propylene glycol monomethyl ether, a solvent containing 40-80% by weight of methyl 2-hydroxyisobutyrate or a solvent containing 10-80% by weight of 3-methoxy-1-butanol. These solvents may be used together.

Other solvent than propylene glycol monomethyl ether, methyl 2-hydroxyisobutyrate and 3-methoxy-1-butanol may be used, taking into account of the improvement of coating performance, profile and solubility of other structural unit in the resin.

As other solvents, esters, glycol ether esters, cyclic esters, ketones and the like can be preferably employed. Specific examples include ethylcellosolve acetate, methylcellosolve acetate, propylene glycol monomethyl ether acetate, ethyl lactate, butyl acetate, amyl acetate, ethyl pyruvate, acetone, methyl isobutyl ketone, 2-heptanone, cyclohexanone, γ-butyrolactone, and the like.

Among these, propylene glycol monomethyl ether acetate and 2-heptanone are preferred because of excellent coating performance and profile of the resulting resist composition.

Examples of preferable combination of the solvents according to the present resist composition include a combination of propylene glycol monomethyl ether and propylene glycol monomethyl ether acetate, a combination of propylene glycol monomethyl ether and 2-heptanone, a combination of propylene glycol monomethyl ether, propylene glycol monomethyl ether acetate and 2-heptanone from the view point of excellent coating performance and profile.

The resin in the resist composition of the present invention contains a structural unit represented by the above formula (I). Among the structural units represented by the above formula (I), those in which R² represents hydrogen are preferred because shapes of the profile of the resulting resist composition are more satisfactory.

As monomers to derive the structural unit represented by the formula (I), specific examples include the following 3-hydroxy-1-adamantyl acrylate, 3-hydroxy-1-adamantyl methacrylate, 3,5-dihydroxy-1-adamantyl acrylate, 3,5-dihydroxy-1-adamantyl methacrylate, and the like. These can be produced by a reaction between corresponding hydroxy adamantane and a (meth)acrylic acid (for example, see JP-A-1988-33350).

In addition, the resin in the present resin composition itself is insoluble or slightly soluble in an aqueous alkali solution but becomes soluble in an aqueous alkali solution by the action of an acid. Specifically, said resins include those not only having the structural unit represented by the above general formula (I) but also having a structural unit that becomes soluble in an aqueous alkali solution through cleavage of a part of groups by the action of an acid.

Specific groups that are cleaved by the action of an acid include groups represented by RCOO—, wherein R represents an aliphatic group, an alicyclic group or an aliphatic group substituted with an alicyclic group. Examples may include C1-6 alkylcarbonyloxy groups such as tert-butylcarbonyloxy group; acetal type carbonyloxy groups such as methoxymethylcarbonyloxy group, ethoxymethylcarbonyloxy group, 1-ethoxyethylcarbonyloxy group, 1-isobutoxyethylcarbonyloxy group, 1-isopropoxyethylcarbonyloxy group, 1-ethoxypropylcarbonyloxy group, 1-(2-methoxyethoxy)ethylcarbonyloxy group, 1-(2-acetoxyethoxy)ethylcarbonyloxy group, 1-[2-(1-adamantyloxy)ethoxy]ethylcarbonyloxy group, 1-[2-(1-adamantancarbonyloxy)ethoxy]ethylcarbonyloxy group, tetrahydro-2-furylcarbonyloxy group and tetrahydro-2-pyranylcarbonyloxy group; alicyclic carbonyloxy groups such as 2-adamantyl-2-alkylcarbonyloxy group, 1-adamantyl-1-alkylalkylcarbonyloxy group, isobornylcarbonyloxy group; and the like.

Examples of monomers used for deriving such resins having a structural unit that has an group represented by RCOO— and that is cleaved by the action of an acid to become soluble in an aqueous alkaline solution may include: acrylic acid type esters such as methacrylic esters and acrylic esters; alicyclic type carboxylates such as norbornenecarboxylates, tricyclodecenecarboxylates and tetracyclodecenecarboxylates; as well as those of alicyclic type carboxylates in which alicyclic group further forms ester with acrylic or methacrylic acid, as described in Journal of Photopolymer Science and Technology, Vol.9, No.3, pages 447-456 (1996) by Iwasa et al.

Among these alicyclic type carboxylic acid esters, those having a bulky group as an alicyclic group such as 2-adamantyl-2-alkyl, 1-adamantyl-1-alkyl, and the like, are preferred because excellent resolution of the resulting resist composition can be achieved.

Examples of such alicyclic type carboxylic acid esters include 2-adamantyl-2-alkyl (meth)acrylate, 1-adamantyl-1-alkylalkyl (meth)acrylate, 2-adamantyl-2-alkyl 5-norbornene-2-carboxylate, 1-adamantyl-1-alkylalkyl 5-norbornene-2-carboxylate and the like.

In particular, using 2-adamantyl-2-alkyl (meth)acrylate as a monomer is particularly preferred because excellent resolution can be achieved. Typical examples of the 2-adamantyl-2-alkyl (meth)acrylate include e.g., 2-adamantyl-2-methyl acrylate, 2-adamantyl-2-methyl methacrylate, 2-adamantyl-2-ethyl acrylate, 2-adamantyl-2-ethyl methacrylate, 2-adamantyl-2-n-butyl acrylate and the like.

Among these, using 2-adamantyl-2-ethyl (meth)acrylate is particularly preferred because well-balanced sensitivity and heat resistance of the resulting resist composition can be achieved.

The resin used in the present invention may also include other structural unit as needed in addition to the structural unit represented by the formula (I) and the structural unit that becomes soluble in an aqueous alkali solution upon cleavage of a part of the groups by the action of an acid.

Examples of such other structural unit include structural units represented by the following formula (II), structural units derived from an unsaturated dicarboxylic acid anhydride selected from maleic anhydride and itaconic anhydride, structural units represented by the following formula (III), structural units represented by the following formula (IVa), structural units represented by the following formula (IVb), structural units represented by meth(acrylonitrile), and the like.

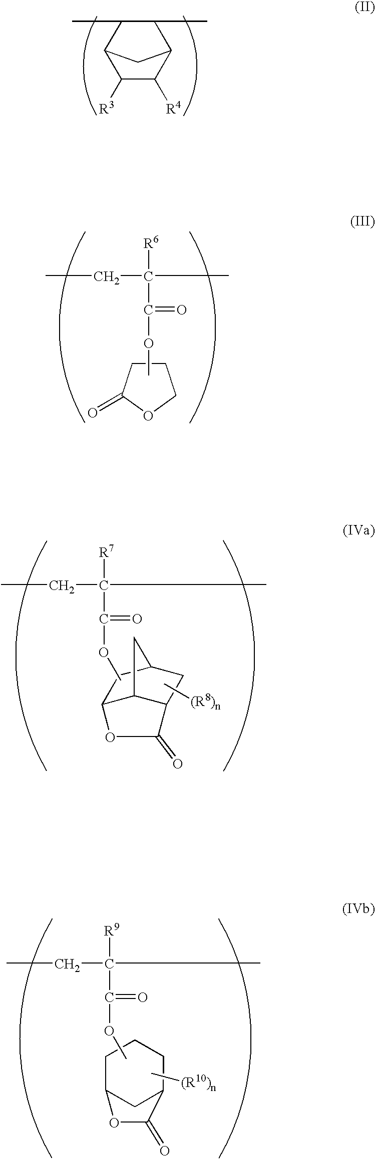

wherein R⁶, R⁷ and R⁹ each independently represent hydrogen or methyl, and R⁸ and R¹⁰ represent methyl. “n” represents a numeral of from 1 to 3. R³ and R⁴ each independently represent hydrogen, alkyl having 1 to 3 carbon atoms, hydroxyalkyl having 1 to 3 carbon atoms, carboxyl, cyano or a group represented by —COOR⁵, wherein R⁵ represents an alcohol residue, or alternatively, R³ and R⁴ may together form a group represented by —C(═O)OC(═O)—.

Examples of the alkyl having 1 to 3 carbon atoms in R³ or R⁴ include methyl, ethyl, propyl and the like. Examples of the hydroxyalkyl having 1 to 3 carbon atoms in R³ or R⁴ include hydroxymethyl, 2-hydroxyethyl and the like.

The group represented by —COOR⁵ in R³ or R⁴ is an esterified group obtained by substituting a carboxyl group with an alcohol. Alcohol residues corresponding to R⁵ include for example, unsubstituted or substituted alkyl having about 1 to 8 carbon atoms, 2-oxoxolane-3-yl, 2-oxoxolane-4-yl or the like. Examples of the substituents for the substituted alkyl having 1 to 8 carbon atoms include a hydroxyl group and an alicyclic hydrocarbon residue.

When R³ or R⁴ represents a group which is represented by —COOR⁵, specific examples thereof include methoxycarbonyl, ethoxycarbonyl, 2-hydroxyethoxycarbonyl, tert-butoxycarbonyl, 2-oxoxolane-3-yloxycarbonyl, 2-oxoxolane-4-yloxycarbonyl, 1,1,2-trimethylpropoxycarbonyl, 1-cyclohexyl-1-methylethoxycarbonyl, 1-(4-methylcyclohexyl)-1-methylethoxycarbonyl, 1-(1-adamantyl)-1-methylethoxycarbonyl and the like.

Further, specific examples of the monomer used to derive the structural unit represented by the formula (II) may include the followings;

2-norbornene,

2-hydroxy-5-norbornene,

5-norbornen-2-carboxylic acid,

methyl 5-norbornen-2-carboxylate,

t-butyl 5-norbornen-2-carboxylate,

1-cyclohexyl-1-methylethyl 5-norbornen-2-carboxylate,

1-(4-methylcyclohexyl)-1-methylethyl 5-norbornen-2-carboxylate,

1-(4-hydroxycyclohexyl)-1-methylethyl 5-norbornen-2-carboxylate,

1-methyl-1-(4-oxocyclohexyl)ethyl 5-norbornen-2-carboxylate,

1-(1-adamantyl-1-methylethyl 5-norbornen-2-carboxylate,

1-methylcyclohexyl 5-norbornen-2-carboxylate,

2-methyl-2-adamantyl 5-norbornen-2-carboxylate,

2-ethyl-2-adamantyl 5-norbornen-2-carboxylate,

2-hydroxyethyl 5-norbornen-2-carboxylate,

5-norbornen-2-methanol,

5-norbornen-2, 3-dicarboxylic acid anhydride, and the like.

Structural units derived from an unsaturated dicarboxylic acid anhydride selected from maleic anhydride and itaconic anhydride can be represented by the following formula (V) and the following formula (VI). Specific monomers used for deriving these structural units include maleic anhydride, itaconic anhydride and the like.

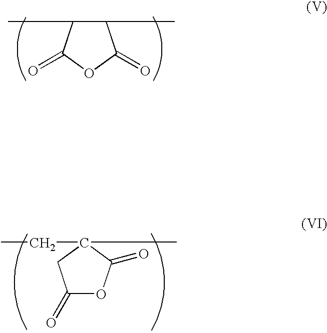

Specific examples of the monomers used for deriving the structural units represented by the formula (III) include the followings;

α-acryloyloxy-γ-butyrolactone,

α-methacryloyloxy-γ-butyrolactone,

β-acryloyloxy-γ-butyrolactone,

β-methacryloyloxy-γ-butyrolactone and the like.

These can be produced by for example, a reaction between corresponding hydroxy α-γ-butyrolactone or hydroxy β-γ-butyrolactone and a (meth)acrylic acid.

Furthermore, specific examples of monomers used for deriving the structural units represented by the formula (IVa) or (IVb) include the following compounds obtained by (meth)acrylate esterification of an alicyclic lactone having a hydroxyl group as represented by the following formulae. These may be used alone or in combination as a mixture of two or more, as needed

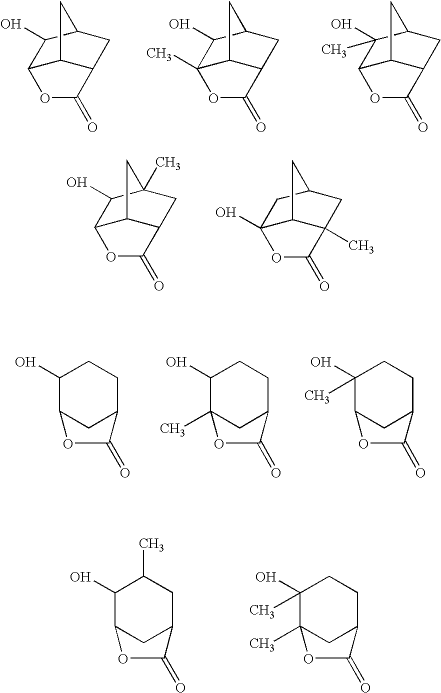

Theses esters can be produced by for example, a reaction between corresponding alicyclic lactone having a hydroxyl group and a (meth)acrylic acid (for example, see JP-A-2000-26446).

The resin used in the present invention preferably has the structural unit represented by the formula (I) in the range of 5-50% by weight based on the total weight of the resin although the preferable range may vary depending on the kind of radiation used for patterning exposure and the kind of the other optionally used structural units.

The resin used for the present invention can be produced in accordance with a conventional copolymerization reaction. For example, the resin used for the present invention can be obtained by dissolving each of the required monomers in an organic solvent and subjecting to a polymerization reaction in the presence of a polymerization initiator such as an azo compound or the like, e.g., 2,2′-azo-bisisobutyronitrile and dimethyl 2,2′azobis(2-methylpropionate). After completion of the reaction, it is advantageous to purify the resin by a procedure such as reprecipitation or the like.

It is preferred that the acid generating agent is a substance which is decomposed to generate an acid by applying radiation such as a light, an electron beam or the like on the substance itself or on a resist composition containing the substance. The acid generated from the acid generating agent acts on the resin described above, leading to cleavage of the group existing in the resin that is to be cleaved by the action of an acid. Examples of such acid generating agents include onium salt compounds, organo-halogen compounds, sulfone compounds, sulfonate compounds and the like.

Specific examples of the acid generating agents include the following compounds.

Diphenyliodonium trifluoromethanesulfonate,

4-methoxyphenylphenyliodinium hexafluoroantimonate,

4-methoxyphenylphenyliodinium trifluoromethanesulfonate,

bis(4-tert-butylphenyl)iodonium tetrafluoroborate

bis(4-tert-butylphenyl)iodonium hexafluorophosphate,

bis(4-tert-butylphenyl)iodonium hexafluoroantimonate

bis(4-tert-butylphenyl)iodonium trifluoromethanesulfonate,

bis(4-tert-butylphenyl)iodonium camphorsulfonate,

triphenylsulfonium hexafluorophosphate,

triphenylsulfonium hexafluoroantimonate,

triphenylsulfonium trifluoromethanesulfonate,

4-methoxyphenyldiphenylsulfonium hexafluoroantimonate,

4-methoxyphenyldiphenylsulfonium trifluoromethanesulfonate,

p-tolyldiphenylsulfonium trifluoromethanesulfonate,

p-tolyldiphenylsulfonium perfluorobutanesulfonate,

p-tolyldiphenylsulfonium perfluorooctanesulfonate,

2,4,6-trimethylphenyldiphenylsulfonium trifluoromethanesulfonate,

4-tert-butylphenyldiphenylsulfonium trifluoromethanesulfonate,

4-phenylthiophenyldiphenylsulfonium hexafluorophosphate,

4-phenylthiophenyldiphenylsulfonium hexafluoroantimonate,

1-(2-naphtholylmethyl)thiolanium hexafluoroantimonate,

1-(2-naphtholylmethyl)thiolanium trifluoromethanesulfonate,

4-hydroxy-1-naphthyldimethylsulfonium hexafluoroantimonate,

4-hydroxy-1-naphthyldimethylsulfonium trifluoromethanesulfonate,

cyclohexylmethyl(2-oxocyclohexyl)sulfonium trifluoromethane sulfonate, cyclohexylmethyl(2-oxocyclohexyl)sulfonium perfluorobutanesulfonate,

cyclohexylmethyl(2-oxycyclohexyl)sulfonium perfluorootcanesulfonate,

2-methyl-4,6-bis(trichloromethyl)-1,3,5-triazine,

2,4,6-tris(trichloromethyl)-1,3,5-triazine

2-phenyl-4,6-bis(trichloromethyl)-1,3,5-triazine,

2-(4-chlorophenyl)-4,6-bis(trichloromethyl)-1,3,5-triazine,

2-(4-methoxyphenyl)-4,6-bis(trichloromethyl)-1,3,5-triazine,

2-(4-methoxy-1-naphthyl)-4,6-bis(trichloromethyl)-1,3,5-triazine,

2-(benzo[d][1,3]dioxolan-5-yl)-4,6-bis(trichloromeythyl)-1,3,5-triazine,

2-(4-methoxystyryl)-4,6-bis(trichloromethyl)-1,3,5-triazine,

2-(3,4,5-trimethoxystyryl)-4,6-bis(trichloromethyl)-1,3,5-triazine,

2-(3,4-dimethoxystyryl)-4,6-bis(trichloromethyl)-1,3,5-triazine,

2-(2,4-dimethoxystyryl)-4,6-bis(trichloromethyl)-1,3,5-triazine,

2-(2-methoxystyryl)-4,6-bis(trichloromethyl)-1,3,5-triazine,

2-(4-butoxystyryl)-4,6-bis(trichloromethyl)-1,3,5-triazine,

2-(4-pentyloxystyryl)-4,6-bis(trichloromethyl)-1,3,5-triazine,

diphenyl disulfone,

di-p-tolyl disulfone

bis(phenylsulfonyl)diazomethane,

bis(4-chlorophenylsulfonyl)diazomethane,

bis(p-tolylsulfonyl)diazomethane,

bis(4-tert-butylphenylsulfonyl)diazomethane,

bis(2,4-xylylsulfonyl)diazomethane,

bis(cyclohexylsulfonyl)diazomethane,

(benzoyl)(phenylsulfonyl)diazomethane,

1-benzoyl-1-phenylmethyl p-toluenesulfonate (generally called “benzoin tosylate”),

2-benzoyl-2-hydroxy-2-phenylethyl p-toluenesulfonate (generally called α-methylolbenzoin tosylate),

1,2,3-benzene-tri-yl tris(methanesulfonate),

2,6-dinitrobenzyl p-toluenesulfonate,

2-nitrobenzyl p-toluenesulfonate,

4-nitrobenzyl p-toluenesulfonate,

N-(phenylsulfonyloxy)succinimide,

N-(trifluoromethylsulfonyloxy)succinimide,

N-(trifluoromethylsulfonyloxy)phthalimide,

N-(trifluoromethylsulfonyloxy)-5-norbornene-2,3-dicarboxyimide,

N-(trifluoromethylsulfonyloxy)naphthalimide,

N-(10-camphorsulfonyloxy)naphthalimide and the like.

In addition, when the present resist composition is the one used for a positive resist composition, performance deterioration due to the deactivation of an acid associated with leaving after exposure can be reduced by adding basic compounds, particularly basic nitrogen-containing organic compounds such as an amine. Specific examples of such basic compounds include the ones represented by the following formulae:

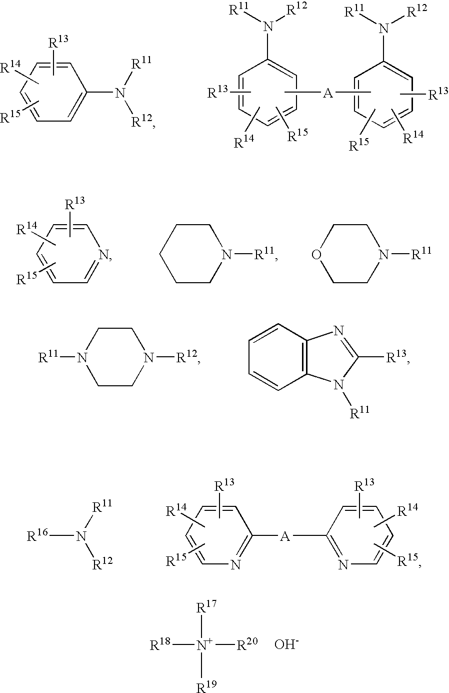

wherein R¹¹ and R¹² represent each independently hydrogen, alkyl, cycloalkyl, aryl or alkoxy. The alkyl preferably has about 1 to 6 carbon atoms, the cycloalkyl preferably has about 5 to 10 carbon atoms, the aryl preferably has about 6 to 10 carbon atoms, and the alkoxy preferably has about 1 to 6 carbon atoms. Furthermore, at least one hydrogen on the alkyl, cycloalkyl, aryl or alkoxy each independently may be substituted with a hydroxyl group, an amino group, or an alkoxy group having 1 to 6 carbon atoms. At least one hydrogen on the amino group each independently may be substituted with an alkyl group having 1 to 4 carbon atoms.

R¹³, R¹⁴ and R¹⁵ each independently represent hydrogen, alkyl, cycloalkyl, aryl or alkoxy. The alkyl preferably has about 1 to 6 carbon atoms, the cycloalkyl preferably has about 5 to 10 carbon atoms, the aryl preferably has about 6 to 10 carbon atoms, and the alkoxy preferably has about 1 to 6 carbon atoms. Furthermore, at least one hydrogen on the alkyl, cycloalkyl, aryl or alkoxy each independently may be substituted with a hydroxyl group, an amino group, or an alkoxy group having 1 to 6 carbon atoms. At least one hydrogen on the amino group may be substituted with an alkyl group having 1 to 4 carbon atoms.

R¹⁶ represents alkyl or cycloalkyl. The alkyl preferably has about 1 to 6 carbon atoms, and the cycloalkyl preferably has about 5 to 10 carbon atoms. Furthermore, at least one hydrogen on the alkyl or cycloalkyl each independently may be substituted with a hydroxyl group, an amino group, or an alkoxy group having 1 to 6 carbon atoms. At least one hydrogen on the amino group may be substituted with an alkyl group having 1 to 4 carbon atoms.

R¹⁷, R¹⁸, R¹⁹ and R²⁰ each independently represent alkyl, cycloalkyl, aryl or alkoxy. The alkyl preferably has about 1 to 6 carbon atoms, the cycloalkyl preferably has about 5 to 10 carbon atoms, the aryl preferably has about 6 to 10 carbon atoms, and the alkoxy preferably has about 1 to 6 carbon atoms. Furthermore, at least one hydrogen on the alkyl, cycloalkyl, aryl or alkoxy each independently may be substituted with a hydroxyl group, an amino group, or an alkoxy group having 1 to 6 carbon atoms. At least one hydrogen on the amino group each independently may be substituted with an alkyl group having 1 to 4 carbon atoms.

A represents alkylene, carbonyl, imino, sulfide or disulfide. The alkylene preferably has about 2 to 6 carbon atoms.

Moreover, among R¹¹-R²⁰, in regard to those which can be straight-chained or branched, either of these may be permitted.

Weight percentage of the resin based on total weight of the resin and acid generating agent in the resist composition of the present invention is preferably 80 to 99.9% by weight.

When a basic compound is used in the composition of the present invention, it is preferred that the composition preferably contains the basic compound in the range of 0.001 to 1 part by weight, particularly in the range of 0.01 to 0.3 part by weight based on 100 parts by weight of the resin.

The resist composition of the present invention may also contain a small amount of various additives such as sensitizers, dissolution inhibitors, resins other than the above resin, surfactants, stabilizers, and dyes as long as the effect of the present invention is not obstructed.

The resist composition of the present invention generally becomes a liquid resist composition under the circumstances in which each of the above-described components is dissolved in a solvent. The liquid resist composition is applied on a substrate such as a silicon wafer according to a usual procedure such as spin coating.

The resist film applied on a substrate, and dried is subjected to an exposure treatment for patterning. Then, after a heat-treatment for promoting a deprotecting reaction, development by an alkali developer is conducted. The alkali developer used herein can be various kinds of aqueous alkaline solutions used in this art. In general, an aqueous solution of tetramethylammonium hydroxide or (2-hydroxyethyl)trimethylammonium hydroxide (generally referred to as colline) is often used.

Although embodiments of the present invention are explained herein above, the embodiments of the present invention disclosed above are made just for illustrative purposes. Accordingly, scope of the present invention is not limited to these embodiments. The scope of the present invention is imparted by accompanying scope of claims, further including all variations within equivalent principles and ranges of the scope of the claims.

The present invention will be described in more detail with reference to examples, which should not be construed as limiting the scope of the present invention. All parts for representing the amount employed in examples are by weight unless otherwise stated. The weight-average molecular weight is a value determined from gel permeation chromatography using polystyrene as a reference standard.

Resin Synthesis Example 1: Production of Resin A1

To a 200 ml flask were charged 20.00 g of 2-ethyl-2-adamantyl methacrylate, 9.52 g of 3-hydroxy-1-adamantyl methacrylate and 6.85 g of α-methacryloyloxy-γ-butyrolactone, and then 90.93 g of methyl isobutyl ketone was further charged as a solvent thereto to give a solution. Following elevating the temperature of the solution to 85° C., 0.53 g of 2,2′-azo-bisisobutyronitrile was added to the mixture as a polymerization initiator to allow the reaction. After keeping the mixture at a temperature of 85° C. for 5 hours followed by cooling, the reaction mixture was added dropwise into a large quantity of methanol to precipitate the resulting copolymer for purification. Through repeating this purification operation three times, copolymer was obtained having molecular weight of 10000 and a degree of dispersion of 1.45. This copolymer is referred to as Resin A1.

Resin Synthesis Example 2: Production of Resin A2

2-Ethyl-2-adamantyl methacrylate, 3-hydroxy-1-adamantyl acrylate and 5-acryloyloxy-2,6-norbornanelactone were charged at a molar ratio of 3:1:6, and thereto was added 2.5 times by weight of 1,4-dioxane based on total weight of the monomers to give a solution. To this solution, was added 2,2′-azo-bisisobutyronitrile as an initiator at 3% by mol based on total amount of the monomer, and the mixture was heated at 87° C. for about 6 hours. Thereafter, an operation of pouring the mixture into a large quantity of methanol was repeated three times to precipitate the resulting copolymer for purification. Consequently, copolymer was obtained having weight-average molecular weight of 11,900. This copolymer is referred to as Resin A2.

Resin Synthesis Example 3: Production of Resin A3

To a 200 ml flask were charged 18.87 g of 2-methyl-2-adamantyl methacrylate, 9.52 g of 3-hydroxy-1-adamantyl methacrylate and 6.85 g of α-methacryloyloxy-γ-butyrolactone, and then 90.93 g of methyl isobutyl ketone was further charged as a solvent thereto to give a solution. Following elevating the temperature of the solution to 85° C., 0.80 g of 2,2′-azo-bisisobutyronitrile was added to the mixture as a polymerization initiator to allow the reaction. After keeping the mixture at a temperature of 85° C. for 5 hours followed by cooling, the reaction mixture was added dropwise into a large quantity of methanol to precipitate the resulting copolymer for purification. Through repeating the purification operation three times, copolymer was obtained having molecular weight of 11000 and a degree of dispersion of 1.45. This copolymer is referred to as Resin A3.

Next, in addition to each of the resins obtained by the above Resin Synthesis Examples, further examples are illustrated in which acid generating agents, quenchers and solvents shown below are used to prepare and evaluate resist compositions.

### EXAMPLES AND COMPARATIVE EXAMPLES

Each of the components listed below was mixed and dissolved, followed by filtration through a fluorine resin filter having pore size of 0.2 μm to prepare a resist comoposition.

Resin (Kinds are described in Table 1 and Table 2.)

Acid generating Agent

C1: p-tolyldiphenylsulfonium perfluorooctanesulfonate

C2: cyclohexylmethyl(2-oxocyclohexyl)sulfonium trifluoromethanesulfonate

C3: p-tolyldiphenylsulfonium trifluoromethanesulfonate

Quencher: 2,6-diisopropylaniline

Solvent: (Weight Ratio in the Solvent is Described in Table 3 and Table 4 With the Following Abbreviations.)

propylene glycol monomethyl ether: E

methyl 2-hydroxyisobtyrate: I

3-methoxy-1-butanol: M

propylene glycol monomethyl ether acetate: A

2-heptanone: H

γ-butyrolactone: G

On a silicon wafer, was applied a composition for organic reflection-preventing membrane “NCA-462” manufactured by Brewer Co. Ltd., and baked under conditions of 215° C. for 60 seconds so that an organic reflection-preventing membrane having a thickness of 780 angstrom was formed on the wafer. The resist solution prepared as above was applied by spin-coating on the wafer so that the film thickness after drying became the film thickness shown in Table 1-Table 3, columns “Film thickness”. After applying the resist solution, the wafer was pre-baked on a direct hotplate at a temperature shown in Table 1-Table 3, columns “PB” for 60 seconds.

The wafer having a resist film thus formed thereon was exposed using an ArF eximer stepper [“NSR ArF”, manufactured by Nikon, NA=0.55, σ=0.6] through a line-and-space pattern, while changing the exposure amount stepwise.

After the exposure, the wafer was subjected to post-exposure baking on a hot plate at a temperature shown in Table 1-Table 3, columns “PEB” for 60 seconds. Then the wafer was subjected to paddle development with 2.38% by weight aqueous tetramethyl ammonium hydroxide solution for 60 seconds.

The developed bright field pattern on the substrate having an organic reflection-preventing membrane was observed by a scanning electron microscope, and the effective sensitivity and the resolution were determined by the following methods. Thus obtained results are illustrated in Table 4-Table 8.

A bright field pattern herein is obtained by exposure and development through a reticle comprising an outer frame formed of a chromium layer (lightproof layer) and linear chromium layers (lightproof layers) formed on a surface of a glass substrate (light-transmissive part). Accordingly, after exposure and development, parts of the resist layer surrounding a line and space pattern are removed with a part of the resist layer corresponding to the outer frame being left outside the line and space pattern.

Methods for Evaluation Illustrated in Table 1, Table 2, Table 4, Table 5, Table 6 and Table 7 (Composition 1 and Composition 2)

Effective sensitivity: expressed as the amount of exposure which renders 0.13 μm isolated line pattern become 0.13 μm.

Resolution: expressed as minimum size of an isolated line pattern formed at the exposure amount of the effective sensitivity.

Solubility: absence of resin precipitate was evaluated as “◯”, and presence of resin precipitate was evaluated as “X”, after preserving at −15° C. for one day.

Methods for Evaluation Illustrated in Table 3 and Table 8 (Composition 3)

Effective sensitivity: expressed as the amount of exposure which gave 1:1 line-and-space pattern of 0.18 μm.

Resolution: expressed as the minimum size which gave line-and-space pattern split at the exposure amount of the effective sensitivity.

Solubility: absence of resin precipitate was evaluated as “◯”, and presence of resin precipitate was evaluated as “X”, after preserving at −15° C. for one day.

TABLE 1
Composition 1

| Acid | | | | | | | | |
|---|---|---|---|---|---|---|---|---|
| generating | | | | | | Film | | |
| agent | | Resin | | | | thickness | PB | PEB |
| (C1/C2) | | A1 | | Quencher | | (μm) | (° C.) | (° C.) |
| 0.2/0.25 | part | 10 | parts | 0.02 | part | 0.34 | 110 | 115 |

TABLE 2
Composition 2

| Acid | | | | | | | | |
|---|---|---|---|---|---|---|---|---|
| generating | | | | | | Film | | |
| agent | | Resin | | | | thickness | PB | PEB |
| (C1/C2) | | A2 | | Quencher | | (μm) | (° C.) | (° C.) |
| 0.2/0.25 | part | 10 | parts | 0.02 | part | 0.34 | 110 | 115 |

TABLE 3
Composition 3

| Acid | | | | | | | | |
|---|---|---|---|---|---|---|---|---|
| generating | | | | | | Film | | |
| agent | | Resin | | | | thickness | PB | PEB |
| (C3) | | A3 | | Quencher | | (μm) | (° C.) | (° C.) |
| 0.2 | part | 10 | parts | 0.015 | part | 0.38 | 150 | 130 |

TABLE 4
Composition 1

| | | Effective | | |
|---|---|---|---|---|
| | Solvent | sensitivity | Resolution | |
| Example No. | (E/A/G) | (mJ/cm²) | (μm) | Solubility |
| Example 1 | 10/90/0 | 25 | 0.11 | ◯ |
| Example 2 | 20/80/0 | 27.5 | 0.11 | ◯ |
| Example 3 | 40/60/0 | 30 | 0.11 | ◯ |
| Example 4 | 20/78/2 | 27.5 | 0.11 | ◯ |
| Example 5 | 20/75/5 | 33.5 | 0.12 | ◯ |
| Comparative | 0/100/0 | 26 | 0.11 | X |
| example 1 | | | | |
| Comparative | 0/98/2 | 27.5 | 0.11 | X |
| example 2 | | | | |
| Comparative | 0/95/5 | 30.5 | 0.12 | X |
| example 3 | | | | |

TABLE 5
Composition 1

| | | Effective | | |
|---|---|---|---|---|
| | Solvent | sensitivity | Resolution | |
| Example No. | (I/A) | (mJ/cm²) | (μm) | Solubility |
| Example 6 | 40/60 | 21 | 0.11 | ◯ |
| Example 7 | 50/50 | 23 | 0.11 | ◯ |

TABLE 6
Composition 1

| | | Effective | | |
|---|---|---|---|---|
| | Solvent | sensitivity | Resolution | |
| Example No. | (M/A) | (mJ/cm²) | (μm) | Solubility |
| Example 8 | 10/90 | 24 | 0.11 | ◯ |
| Example 9 | 20/80 | 24 | 0.11 | ◯ |
| Example 10 | 40/60 | 20 | 0.11 | ◯ |
| Example 11 | 50/50 | 24 | 0.11 | ◯ |

TABLE 7
Composition 2

| | | Effective | | |
|---|---|---|---|---|
| | Solvent | sensitivity | Resolution | |
| Example No. | (E/H/A) | (mJ/cm²) | (μm) | Solubility |
| Example 12 | 10/45/45 | 31 | 0.11 | ◯ |

TABLE 8
Composition 3

| | | Effective | | |
|---|---|---|---|---|
| | Solvent | sensitivity | Resolution | |
| Example No. | (E/A/G) | (mJ/cm²) | (μm) | Solubility |
| Example 13 | 10/90/0 | 20 | 0.15 | ◯ |
| Example 14 | 20/80/0 | 20 | 0.15 | ◯ |
| Example 15 | 40/60/0 | 23 | 0.15 | ◯ |
| Example 16 | 20/78/2 | 20 | 0.15 | ◯ |
| Example 17 | 20/75/5 | 23 | 0.15 | ◯ |
| Example 18 | 60/40/0 | 23 | 0.15 | ◯ |
| Example 19 | 75/25/0 | 19 | 0.15 | ◯ |
| Comparative | 0/100/0 | 20 | 0.15 | X |
| example 4 | | | | |
| Comparative | 0/98/2 | 20 | 0.15 | X |
| example 5 | | | | |
| Comparative | 0/95/5 | 21.5 | 0.15 | X |
| example 6 | | | | |

As is clear from Tables, the resist compositions of the Examples were more excellent in their solubility in comparison with the Comparative Examples without deposition of the resin at a low temperature of −15° C., while exhibiting no deteriorated balance of the performances.

The resist composition of the present invention exhibits well-balanced performances in terms of resolution and sensitivity, and has satisfactory solubility. Therefore, the present resist composition is suitably used as a positive resist composition. Accordingly, the present composition is suitable for exposure in which KrF excimer laser, KrF excimer laser or the like is used, thereby providing a resist pattern, in particular a positive resist pattern, with high performances.

What is claimed is:

1. A resist composition comprising: a resin which has a structural unit represented by the following formula (I) 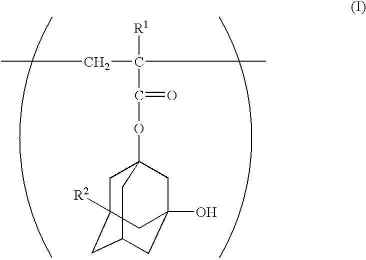
wherein R¹ represents hydrogen or methyl and R² represents hydrogen or hydroxyl, and which itself is insoluble or slightly soluble in an aqueous alkali solution but becomes soluble in an aqueous alkali solution by the action of an acid; a solvent containing at least one selected from the group consisting of propylene glycol monomethyl ether, methyl 2-hydroxyisobtyrate and 3-methoxy-1-butanol; and an acid generating agent.

2. The composition according to claim 1, wherein the solvent is a solvent containing at least 10% by weight of propylene glycol monomethyl ether, a solvent containing at least 40% by weight of methyl 2-hydroxyisobtyrate or a solvent containing at least 10% by weight of 3-methoxy-1-butanol.

3. The composition according to claim 1, wherein the solvent further contains at least one selected from the group consisting of propylene glycol monomethyl ether acetate and 2-heptanone.

4. The composition according to claim 1, wherein R² is hydrogen in the structural unit represented by the formula (I).

5. The composition according to claim 1, wherein weight percentage of the resin based on total weight of the resin and acid generating agent is 80-99.9% by weight.

6. The composition according to claim 1, wherein the percentage content of the structural unit represented by the formula (I) is 5-50% by weight in the resin.

7. The composition according to claim 1, wherein the resin further has a structural unit having a group which is cleaved by the action of an acid.

8. The composition according to claim 7, wherein the structural unit having a group which is cleaved by the action of an acid is a structural unit derived from 2-alkyl-2-adamantyl (meth)acrylate.

9. The composition according to claim 1 further comprising a basic compound as a quencher.
